(19) United States
(12) Patent Application Publication
(10) Pub. No.: US 2026/0243851 A1
(43) Pub. Date: Aug. 20, 2026

(54) APPARATUS AND METHOD FOR DETERMINING CONNECTION STATE

(71) Applicant: SK On Co., Ltd., Seoul (KR)

(72) Inventors: Tae Woong SHIN, Daejeon (KR); Woo Jung KIM, Daejeon (KR)

(21) Appl. No.: 19/537,523

(22) Filed: Feb. 12, 2026

(30) Foreign Application Priority Data
Feb. 17, 2025 (KR) 10-2025-0020252

(51) Int. Cl. G01R 31/69; B60L 53/16; G01R 31/54

(52) U.S. Cl. CPC G01R 31/69; G01R 31/54; B60L 53/16

(57) ABSTRACT

Proposed are an apparatus and a method for determining a connection state, and the apparatus comprises a determination part comprising a capacitor connected in series to a high-voltage interlock loop comprised in a connector, the determination part being configured to apply a pulse voltage to the high-voltage interlock loop and the capacitor and to measure a voltage charged to or discharged from the capacitor, and a controller configured to determine a connection state of the connector on the basis of the voltage measured by the determination part, wherein the controller calculates a loop resistance of the high-voltage interlock loop by using a time required for the voltage of the capacitor to reach a reference voltage and determines the connection state of the connector as abnormal when the loop resistance exceeds a predetermined value.

### CROSS REFERENCE TO RELATED APPLICATION

The present application claims priority to Korean Patent Application No. 10-2025-0020252, filed on Feb. 17, 2025, the entire contents of which are incorporated herein for all purposes by this reference.

### TECHNICAL FIELD

The present disclosure relates to an apparatus and a method for determining a connection state.

### BACKGROUND

An electric vehicle using a high voltage is required to determine a connection state of a high-voltage connector. A high-voltage interlock loop (HVIL) is a method of monitoring the connection state of the high-voltage connector by using a low-voltage signal connection that is connected together when the high-voltage connector is connected. The high-voltage interlock loop is capable of monitoring the connection state of the high-voltage connector by detecting that the low-voltage signal connection also becomes abnormal when the connection state of the high-voltage connector becomes abnormal. When it is confirmed, by using the high-voltage interlock loop, that the connection state of the connector is abnormal, an alarm signal may be transmitted to a driver.

### SUMMARY

According to an aspect of the present disclosure, there may be provided a connection state determination apparatus comprising a high-voltage interlock loop operated by a voltage source comprised in a battery management system.

According to an aspect of the present disclosure, there may be provided a connection state determination apparatus configured to determine a connection state by applying a pulse voltage to a high-voltage interlock loop comprising a resistor and a capacitor, measuring a charging time of the capacitor, and calculating a resistance value of a low-voltage loop based on the measured charging time.

According to an aspect of the present disclosure, there is provided a connection state determination apparatus comprising: a determination part comprising a capacitor connected in series to a high-voltage interlock loop comprised in a connector, the determination part being configured to apply a pulse voltage to the high-voltage interlock loop and the capacitor and to measure a voltage charged to or discharged from the capacitor, and a controller configured to determine a connection state of the connector on the basis of the voltage measured by the determination part, wherein the controller calculates a loop resistance of the high-voltage interlock loop by using a time required for the voltage of the capacitor to reach a reference voltage and determines the connection state of the connector as abnormal when the loop resistance exceeds a predetermined value.

According to an embodiment, the determination part may further comprise a pulse voltage source configured to supply the pulse voltage, wherein the pulse voltage source may comprise: a voltage source provided inside a battery management system; and a switch connected between an output terminal of the voltage source and ground and configured to be repeatedly turned on and off to generate the pulse voltage.

According to an embodiment, the determination part may comprise: a first capacitor connected in series to a first end of the high-voltage interlock loop; a second capacitor connected in series to a second end of the high-voltage interlock loop; and a voltage measurement part configured to measure a voltage across an equivalent capacitance of the first capacitor and the second capacitor, wherein the first capacitor and the second capacitor may protect the voltage measurement part from a high current generated when a high-voltage line is short-circuited to the high-voltage interlock loop.

According to an embodiment, the determination part may comprise: a first determination part connected to a first end of the high-voltage interlock loop; and a second determination part connected to a second end of the high-voltage interlock loop, wherein the first determination part may comprise: a pulse voltage source configured to output the pulse voltage; a first resistor having a first end connected to the pulse voltage source; a first capacitor connected in series between a second end of the first resistor and the first end of the high-voltage interlock loop; and a first voltage measurement part configured to measure a first voltage at a connection point between the first resistor and the first capacitor, wherein the second determination part may comprise: a second capacitor having a first end connected in series to the second end of the high-voltage interlock loop; a second resistor connected between a second end of the second capacitor and ground; and a second voltage measurement part configured to measure a second voltage at a connection point between the second capacitor and the second resistor.

According to an embodiment, the second determination part may comprise: a third resistor connected between the second resistor and the ground; and a diode connected in parallel with the third resistor, with an anode of the diode connected to the ground and a cathode of the diode connected to the second resistor.

According to an embodiment, the determination part and the controller may be provided in a battery management system of a battery pack of an electric vehicle.

According to an embodiment, the time required for the voltage of the capacitor to reach the reference voltage may be a time required for the voltage of the capacitor to reach the reference voltage from a point at which the switch configured to generate the pulse voltage is turned on or off.

According to an embodiment, the controller may calculate the loop resistance by dividing the time required for the voltage of the capacitor to reach the reference voltage by a capacitance value of the capacitor connected in series to the high-voltage interlock loop.

According to the present disclosure, there is provided a connection state determination method comprising: supplying, by a pulse voltage source of a determination part, a pulse voltage to a high-voltage interlock loop comprised in a connector, the high-voltage interlock loop being connected in series with a capacitor of the determination part; measuring, by the determination part, charging or discharging of the capacitor, and determining, by a controller, the connection state of the connector as abnormal when a loop resistance exceeds a predetermined value after calculating the loop resistance of the high-voltage interlock loop by using a time required for a voltage of the capacitor to reach a reference voltage.

According to an embodiment, the pulse voltage source may comprise: a voltage source provided inside a battery management system; and a switch connected between an output terminal of the voltage source and ground and configured to be repeatedly turned on and off to generate the pulse voltage, wherein in the supplying of the pulse voltage, the controller may control the switch to be repeatedly turned on and off.

According to an embodiment, the determination part may comprise: a first capacitor connected in series to a first end of the high-voltage interlock loop; a second capacitor connected in series to a second end of the high-voltage interlock loop; and a voltage measurement part configured to measure a voltage charged to or discharged from an equivalent capacitance of the first capacitor and the second capacitor, wherein the method may further comprise blocking, by the first capacitor and the second capacitor, a high-voltage direct current input from a high-voltage line to the high-voltage interlock loop from flowing into the voltage measurement part, when the high-voltage line is short-circuited to the high-voltage interlock loop.

According to an embodiment, in the measuring of the charging or discharging of the capacitor, the first voltage measurement part may measure the first voltage at the connection point between the first resistor and the first capacitor and provide the first voltage to the controller, and the second voltage measurement part may measure the second voltage at the connection point between the second capacitor and the second resistor and provide the second voltage to the controller.

According to an embodiment, in the determining, the controller may measure a time required for the voltage of the capacitor to reach the reference voltage from a point at which a switch configured to generate the pulse voltage is turned on or off, calculate the loop resistance by dividing the time required for the voltage of the capacitor to reach the reference voltage by a capacitance value of the capacitor connected in series to the high-voltage interlock, and determine the connection state of the connector as abnormal when the loop resistance exceeds a predetermined value.

Features and advantages of the present disclosure will become more apparent from the following detailed description with reference to the accompanying drawings.

Prior to the description, terms and words used in the present specification and claims should not be interpreted in a common or dictionary sense, but should be interpreted with meanings and concepts consistent with the technical spirit of the present disclosure, based on the principle that an inventor may appropriately define the concepts of terms in order to describe his or her invention in the best manner.

According to an embodiment of the present disclosure, a current source installed to supply a constant current to the high-voltage interlock loop may be omitted.

According to an embodiment of the present disclosure, a structure of a determination circuit for monitoring the high-voltage interlock loop is simple.

According to an embodiment of the present disclosure, a capacitor can protect a circuit in the event of a high-voltage short circuit.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a diagram illustrating a circuit of an electric vehicle to which a connection state determination apparatus according to an embodiment is applied;

FIG. 2 is a diagram illustrating the connection state determination apparatus according to an embodiment;

FIG. 3 is a graph illustrating a pulse voltage and a voltage of a capacitor according to an embodiment;

FIG. 4 is a diagram illustrating a case in which a connection state of a high-voltage connector is abnormal according to an embodiment;

FIG. 5 is a graph illustrating a pulse voltage and a voltage of a capacitor in the case in which the connection state of the high-voltage connector is abnormal according to an embodiment; and

FIG. 6 is a flowchart illustrating each step of a connection state determination method according to an embodiment.

### DETAILED DESCRIPTION

Hereinafter, the present disclosure will be described in detail with reference to the accompanying drawings. However, this is merely illustrative, and the present disclosure is not limited to the specific embodiments illustratively described.

Hereinafter, an embodiment of the present disclosure will be described in detail with reference to the accompanying drawings.

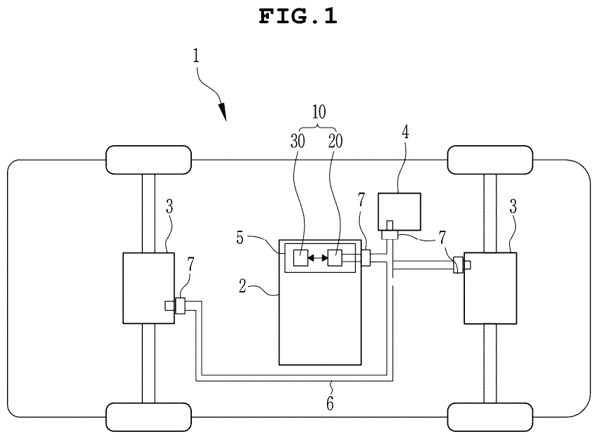

FIG. 1 is a diagram illustrating an electric vehicle 1 to which a connection state determination apparatus 10 according to an embodiment is applied.

The electric vehicle 1 may comprise a high-voltage line (not shown) that supplies power to components in which a high voltage is used, such as a battery pack 2, a motor 3, and a charging part 4. The high-voltage line may connect the battery pack 2 and the motor 3, and may connect the charging unit 4 and the battery pack 2. The electric vehicle 1 may comprise a line to which a relatively low-voltage power source, such as a 12V battery, is connected. A low-voltage line may be connected to devices such as a generator of the electric vehicle 1, a 12V battery, a headlamp, a user interface device, and a black box, to supply power thereto.

The electric vehicle 1 may comprise a plurality of connectors 7 configured to connect the high-voltage line or the low-voltage line. The connectors 7 may be coupled in a manner in which a male connector and a female connector are connected to each other. The connectors 7 may connect a line for transmitting power and a component that supplies or consumes power. When the connection state of each of the connectors 7 connecting the high-voltage line is abnormal, there is a risk that serious problems may occur, comprising the motor 3 not operating. Therefore, it is necessary to determine whether the connection state of the connector 7 is normal or abnormal.

According to an embodiment, the apparatus 10 and method for determining a connection state may determine the connection state of the connector 7 connecting a high-voltage line. The connection state determination apparatus 10 may be comprised in a battery management system 5 of the battery pack 2. The connection state determination apparatus 10 may operate as a part of the battery management system 5. When the connection state determination apparatus 10 determines that the state of the connector 7 connecting the high-voltage line is abnormal, the connection state determination apparatus 10 may notify a driver or a user that the connection of the connector 7 is abnormal. Since the connection state determination apparatus 10 according to an embodiment is comprised in the battery management system 5, the connection state of the high-voltage line may be easily determined without manufacturing a separate circuit.

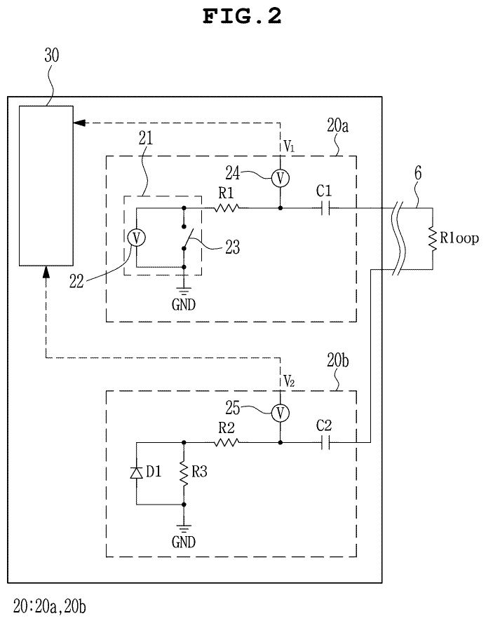

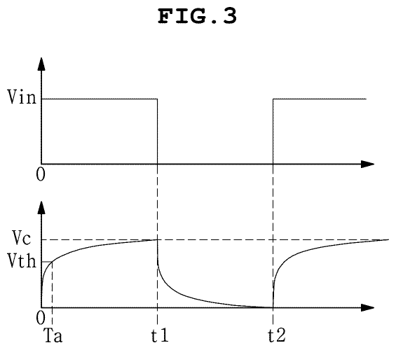

FIG. 2 is a diagram illustrating the connection state determination apparatus 10 according to an embodiment. FIG. 3 is a graph illustrating a pulse voltage and a voltage of a capacitor according to an embodiment. FIG. 2 and FIG. 3 are described with reference to FIG. 1.

The connection state determination apparatus 10 may comprise a determination part 20 comprising a capacitor connected in series to a high-voltage interlock loop 6 comprised in the connector 7, the determination part 20 being configured to apply a pulse voltage to the high-voltage interlock loop 6 and the capacitor and to measure a voltage charged to or discharged from the capacitor, and a controller 30 configured to determine the connection state of the connector 7 on the basis of the voltage measured by the determination part 20. The controller 30 may calculate a loop resistance Rloop of the high-voltage interlock loop 6 by using a time required for the voltage of the capacitor to reach a reference voltage, and may determine the connection state of the connector 7 as abnormal when the loop resistance Rloop exceeds a predetermined value.

As shown in FIG. 1, the high-voltage interlock loop 6 may be connected across the plurality of connectors 7. A loop resistance Rloop illustrated in FIG. 2 may represent an equivalent resistance of the high-voltage interlock loop 6 connected across the plurality of connectors 7. The loop resistance Rloop may comprehensively comprise a contact resistance between the connectors 7 and a resistance of a line constituting the high-voltage interlock loop 6. For example, when a connection state of a connector 7 connected to the battery pack 2, a connection state of a connector 7 connected to the motor 3, and a connection state of a connector 7 connected to the charging part 4 are all normal, the loop resistance Rloop may have a very small value. In contrast, when a connection state of any one of the connector 7 connected to the battery pack 2, the connector 7 connected to the motor 3, and the connector 7 connected to the charging part 4 is abnormal, the loop resistance Rloop may have a relatively large value. The high-voltage interlock loop 6 may be configured to connect the plurality of connectors 7 as a single loop, and even when only one of the connectors 7 has an abnormal connection state, the loop resistance Rloop may have a large value.

The determination part 20 may be connected to the high-voltage interlock loop 6. The determination part 20 may comprise the capacitor, and the capacitor may be connected in series to the high-voltage interlock loop 6. The high-voltage interlock loop 6 may be represented by an equivalent loop resistance Rloop, and the determination part 20 may provide a circuit in which the capacitor is connected in series with the high-voltage interlock loop represented by the loop resistance Rloop. The determination part 20 may apply a pulse voltage to an RC circuit in which a resistor and the capacitor are connected in series. When the pulse voltage is applied to a series RC circuit, the capacitor may repeatedly perform charging and discharging.

The determination part 20 may measure a voltage of the capacitor and provide the measured voltage to the controller 30. The controller 30 may comprise a microcontroller unit. The controller 30 may be implemented as an MCU within the battery management system 5 (BMS).

The controller 30 may count a time required for the voltage of the capacitor to reach the reference voltage. The controller 30 may count a time required for the voltage of the capacitor to reach the reference voltage (about 63% of the pulse voltage), and may calculate the loop resistance Rloop by using a time constant of the series RC circuit (τ=RC, where R is the loop resistance Rloop). When the calculated loop resistance Rloop exceeds a predetermined value, the controller 30 may determine that at least one of the plurality of connectors 7 comprised in the high-voltage interlock loop 6 is in abnormal. When the controller 30 determines that the connector 7 is in an abnormal state, the controller 30 may provide an alarm signal to a driver or a user of a vehicle.

The determination part 20 may further comprise a pulse voltage source 21 configured to supply the pulse voltage. The pulse voltage source 21 may comprise a voltage source 22 provided inside the battery management system 5, and a switch 23 connected between an output terminal of the voltage source 22 and ground (GND) and configured to be repeatedly turned on and off to generate the pulse voltage.

The determination part 20 may supply a pulse voltage to the high-voltage interlock loop 6 rather than supplying a direct current thereto. The determination part 20 may not comprise electronic components for configuring a current source for supplying a direct current to the high-voltage interlock loop 6.

The pulse voltage source 21 may supply a pulse voltage to the high-voltage interlock loop 6 connected in series with the capacitor. The pulse voltage source 21 may comprise the voltage source 22 and the switch 23 connected in parallel with the voltage source 22. A first end of the switch 23 may be connected to the output terminal of the voltage source 22, and a second end of the switch 23 may be connected to ground (GND). When the switch 23 is turned on, a voltage output from the voltage source 22 is connected to ground (GND), such that OV is output, and when the switch 23 is turned off, the voltage output from the voltage source 22 is output as it is. When the switch 23 is repeatedly turned on and off, a square pulse voltage may be output. The switch 23 may be implemented using a field effect transistor (FET). The switch 23 may be repeatedly turned on and off according to a signal output from the controller 30. The voltage source 22 may be a voltage source provided by the battery management system 5 (BMS). The determination part 20 may be provided in the battery management system 5. Since the connection state determination apparatus 10 generates a square pulse voltage by using the voltage source 22 of the battery management system 5 and the field effect transistor, a cost of circuit components may be reduced as compared to a method using a current source.

The determination part 20 may comprise a first capacitor C1 connected in series to a first end of the high-voltage interlock loop 6, a second capacitor C2 connected in series to a second end of the high-voltage interlock loop 6, and a voltage measurement part configured to measure a voltage across an equivalent capacitance of the first capacitor C1 and the second capacitor C2. The first capacitor C1 and the second capacitor C2 may protect the voltage measurement part from a high current generated when a high-voltage line is short-circuited to the high-voltage interlock loop 6.

The determination part 20 may comprise the first capacitor C1 and the second capacitor C2 respectively connected in series to opposite ends of the high-voltage interlock loop 6. When a direct current is applied, the capacitor may substantially operate like an open switch 23. When a high-voltage line comes into contact with the high-voltage interlock loop 6 due to a defect of the connector 7 or various other causes, a high-voltage direct current may flow through the high-voltage interlock loop 6. When a high-voltage direct current is directly delivered to electronic components constituting the determination part 20, there is a risk that the electronic components may be damaged. The first capacitor C1 and the second capacitor C2 of the determination part 20 are respectively connected to the opposite ends of the high-voltage interlock loop 6, and thus when a high-voltage direct current flows into the high-voltage interlock loop 6, the high-voltage direct current may not pass through the first capacitor C1 and the second capacitor C2. Accordingly, when the high-voltage direct current flows in the high-voltage interlock loop 6, the first capacitor C1 and the second capacitor C2 may protect the determination part 20.

For example, a first resistor R1 is connected to the first capacitor C1, the pulse voltage source 21 is connected to the first resistor R1, and a first voltage measurement part 24 is connected to a connection point between the first resistor R1 and the first capacitor C1, so that the first capacitor C1 may protect the first resistor R1, the first voltage measurement part 24, and the pulse voltage source from a high-voltage direct current. In addition, a second resistor R2 is connected to the second capacitor C2, and a second voltage measurement part 25 is connected to a connection point between the second resistor R2 and the second capacitor C2, so that the second capacitor C2 may protect the second resistor R2 and the second voltage measurement part 25 from a high-voltage direct current.

The specific circuit configuration of the determination part 20 will be described. The determination part 20 may comprise a first determination part 20a connected to the first end of the high-voltage interlock loop 6, and a second determination part 20b connected to the second end of the high-voltage interlock loop 6. The first determination part 20a may comprise the pulse voltage source 21 configured to output a pulse voltage, the first resistor R1 having a first end connected to the pulse voltage source 21, the first capacitor C1 connected in series between a second end of the first resistor R1 and the first end of the high-voltage interlock loop 6, and the first voltage measurement part 24 configured to measure a first voltage at a connection point between the first resistor R1 and the first capacitor C1. The second determination part 20b may comprise the second capacitor C2 having a first end connected in series to the second end of the high-voltage interlock loop 6, the second resistor R2 connected between a second end of the second capacitor C2 and ground (GND), and the second voltage measurement part 25 configured to measure a second voltage at a connection point between the second capacitor C2 and the second resistor R2. In addition, the controller 30 may calculate a voltage across an equivalent capacitance of the first capacitor C1 and the second capacitor C2 by using the first voltage and the second voltage, and may calculate a loop resistance Rloop by using the first resistor R1 and the second resistor R2 and compare the calculated loop resistance with a predetermined value.

The first determination part 20a may be connected to the first end of the high-voltage interlock loop 6, and the second determination part 20b may be connected to the second end of the high-voltage interlock loop 6. The first capacitor C1 of the first determination part 20a is directly connected to the first end of the high-voltage interlock loop 6 so as to protect the first determination part 20a from a high-voltage direct current introduced from the high-voltage interlock loop 6. The second capacitor C2 of the second determination part 20b is directly connected to the second end of the high-voltage interlock loop 6 so as to protect the second determination part 20b from a high-voltage direct current introduced from the high-voltage interlock loop 6.

The first determination part 20a may comprise the first voltage measurement part 24, and the second determination part 20b may comprise the second voltage measurement part 25. The first voltage measurement part 24 may measure the first voltage at the connection point between the first resistor R1 and the first capacitor C1, and the second voltage measurement part 25 may measure the second voltage at the connection point between the second resistor R2 and the second capacitor C2. A voltage applied across the first capacitor C1, the loop resistance Rloop, and the second capacitor C2 may be calculated by subtracting the second voltage from the first voltage. Since a capacitor is charged when a direct current voltage is supplied and the capacitor is discharged when the supply of the direct current voltage is stopped, a voltage applied across an equivalent capacitance of the first capacitor C1 and the second capacitor C2 changes as illustrated in FIG. 3.

A time required for a voltage of a capacitor to reach a reference voltage may be a time required for the voltage of the capacitor to reach the reference voltage from a point at which the switch 23 configured to generate the pulse voltage is turned on or off. When the switch 23 is turned on, the capacitor starts to be charged, and when the switch 23 is turned off, the capacitor starts to be discharged.

A magnitude of the pulse voltage may be equal to a magnitude Vin of a voltage output by the voltage source 22. During a pulse-on period from 0 to t1, the first capacitor C1 and the second capacitor C2 may be charged. During the pulse-on period, voltages of the first capacitor C1 and the second capacitor C2 may increase from 0 to Vc. During a pulse-off period from t1 to t2, the first capacitor C1 and the second capacitor C2 may be discharged. During the pulse-off period, the voltages of the first capacitor C1 and the second capacitor C2 may decrease from Vc to 0.

The controller 30 may obtain a time T required for a voltage across an equivalent capacitance of the first capacitor C1 and the second capacitor C2 to increase up to a reference voltage Vth. The time T corresponds to a time constant t.

The controller 30 may calculate a loop resistance Rloop by dividing a time required for a voltage of a capacitor to reach the reference voltage by a capacitance value of a capacitor connected in series to the high-voltage interlock loop 6. In a series RC circuit, a time constant t is a product of a resistance and a capacitance. Accordingly, by measuring the time required for the voltage of the capacitor to reach the reference voltage, using the measured time as the time constant, and dividing the time constant by the capacitance value of the capacitor connected in series to the high-voltage interlock loop 6, the loop resistance Rloop may be obtained. In an embodiment, since the circuit comprises a plurality of capacitors and a plurality of resistors, the loop resistance Rloop may be calculated by using Equation 1 below.

The controller 30 may calculate the loop resistance Rloop by using Equation 1 below. The time T is a measured value, and R1, R2, R3, C1, and C2 are values stored in the controller 30.

$$T = RC = ( R 1 + Rloop + R 2 + R 3 ) ( \frac{1}{\frac{1}{C 1} + \frac{1}{C 2}} ) \qquad [ Equation 1 ]$$

(T: a time required for a voltage across an equivalent capacitance to reach the reference voltage Vth, R1: the first resistor, R2: the second resistor, R3: a third resistor, Rloop: the loop resistance, C1: the first capacitor, C2: the second capacitor)

For example, in FIG. 3, when a time required for a voltage of an equivalent capacitor to reach the reference voltage Vth is Ta, Ta may be inserted into T of Equation 1. The controller 30 may calculate the loop resistance Rloop, and may determine whether the calculated loop resistance Rloop is equal to or greater than a predetermined value. The controller 30 may determine that the connection state of the connector 7 is abnormal when the calculated loop resistance Rloop is equal to or greater than the predetermined value. The controller 30 may determine that the connection state of the connector 7 is normal when the calculated loop resistance Rloop is less than the predetermined value.

The second determination part 20b may comprise the third resistor R3 connected between the second resistor R2 and ground (GND), and a diode D1 connected in parallel with the third resistor R3, with an anode of the diode D1 connected to the ground GND and a cathode of the diode D1 connected to the second resistor R2. The diode D1 may prevent a voltage spike that may occur when the connector 7 of the high-voltage interlock loop 6 is connected.

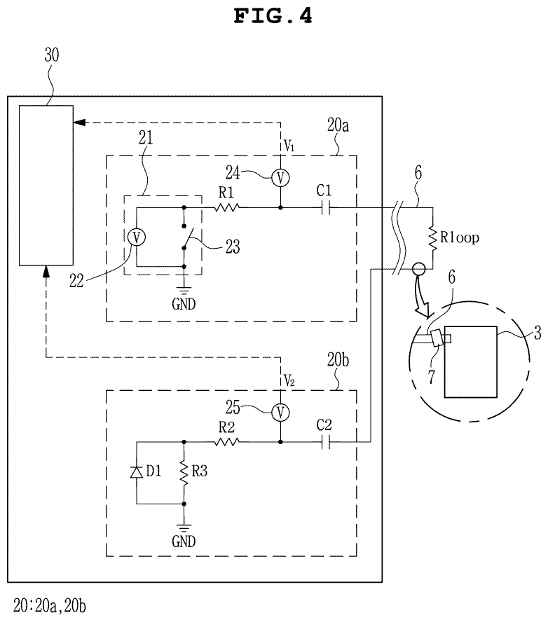

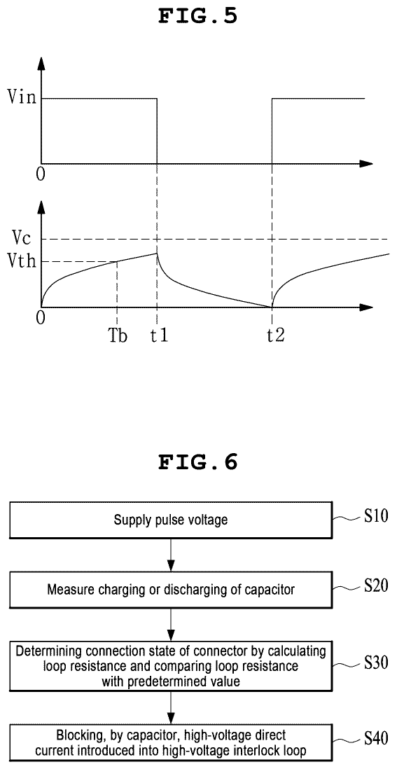

FIG. 4 is a view illustrating a case in which the connection state of the high-voltage connector 7 is abnormal according to an embodiment. FIG. 5 is a graph illustrating a pulse voltage and a voltage of a capacitor when the connection state of the high-voltage connector 7 is abnormal according to an embodiment.

Referring to FIGS. 4 and 5, a case in which the connector 7 is abnormal will be described.

A case in which the connection state of the connector 7 is abnormal may comprise a case in which the connector 7 becomes loose, or a case in which contact resistance increases due to corrosion formed on contact terminals of the connector 7. That is, the abnormal connection state of the connector 7 corresponds to a state in which the loop resistance Rloop, which is an equivalent resistance of the high-voltage interlock loop 6, is increased.

The pulse voltage source 21 may generate a pulse voltage and apply the pulse voltage to the capacitor and the high-voltage interlock loop 6. The first capacitor C1 and the second capacitor C2 may be charged during a period in which a pulse is in an on state (from 0 to t1). The first capacitor C1 and the second capacitor C2 may be discharged during a period in which the pulse is in an off state (from t1 to t2). The first voltage measurement part 24 of the first determination part 20a may measure the first voltage at the connection point between the first resistor R1 and the first capacitor C1 and transmit the measured first voltage to the controller 30. The second voltage measurement part 25 of the second determination part 20b may measure the second voltage at the connection point between the second resistor R2 and the second capacitor C2 and transmit the measured second voltage to the controller 30.

The controller 30 may calculate a voltage applied across the first capacitor C1, the loop resistance Rloop, and the second capacitor C2 by subtracting the second voltage from the first voltage. Charging and discharging of the equivalent capacitor of the first capacitor C1 and the second capacitor C2 are illustrated in FIG. 5.

However, since the loop resistance Rloop is increased, a charging speed of the first capacitor C1 and the second capacitor C2 is reduced. This may be explained by the fact that, in a time constant (t=RC), an increase in the loop resistance Rloop comprised in R causes the charging speed of the capacitor to decrease. Accordingly, as illustrated in FIG. 5, the equivalent capacitor of the first capacitor C1 and the second capacitor C2 may fail to be charged up to Vc, and a time T required to be charged to the reference voltage Vth may increase. For example, in FIG. 5, when a time required for a voltage of the equivalent capacitor to reach the reference voltage Vth is Tb, Tb may be inserted into T of Equation 1.

The controller 30 may input a time Tb, which is required for the capacitor to be charged to the reference voltage, into Equation 1 described above and calculate the loop resistance Rloop. The calculated loop resistance Rloop may be significantly greater than a loop resistance Rloop in a normal state. The controller 30 may determine that the connection state of the connector 7 is abnormal when the loop resistance Rloop is determined to be equal to or greater than a predetermined value.

The determination part 20 and the controller 30 described above may be provided in the battery management system 5 of the battery pack 2 of the electric vehicle 1. Since the determination part 20 described above is a simple circuit comprising only resistors and capacitors, the determination part 20 is convenient to be embedded in the battery management system 5. When the determination part 20 and the controller 30 configured to monitor the high-voltage interlock loop 6 are embedded in the battery management system 5, the battery management system 5 may determine the connection state of the connector 7, thereby enabling integrated battery management.

FIG. 6 is a view illustrating each step of a connection state determination method according to an embodiment. Refer to FIGS. 1 to 3 together with FIG. 6.

The connection state determination method may comprise supplying, by the pulse voltage source 21 of the determination part 20, a pulse voltage to the high-voltage interlock loop 6 comprised in the connector 7, with the high-voltage interlock loop connected in series with the capacitor of the determination part at S10; measuring, by the determination part 20, charging or discharging of the capacitor at S20; and determining, by the controller 30, the connection state of the connector 7 as abnormal when the loop resistance exceeds a predetermined value at S30 after calculating the loop resistance of the high-voltage interlock loop 6 by using a time required for the voltage of the capacitor to reach the reference voltage.

The supplying of the pulse voltage at S10 is a step in which the pulse voltage source 21 generates a pulse voltage and supplies the pulse voltage to the capacitor and the high-voltage interlock loop 6. The supplying of the pulse voltage at S10 may be a step in which the controller 30 controls the switch 23 to be repeatedly turned on and off. The supplying of the pulse voltage at S10 may be continuously and repeatedly performed. The pulse voltage source 21 may comprise the voltage source 22 provided inside the battery management system 5 and the switch 23 connected between the output terminal of the voltage source 22 and the ground GND and configured to repeatedly turn on and off to generate the pulse voltage. In the supplying of the pulse voltage at S10, the controller 30 may control the switch 23 to be repeatedly turned on and off. When the pulse voltage is supplied, the capacitor may repeatedly perform charging and discharging.

The measuring of the charging or discharging of the capacitor at S20 is a step of measuring the charging or discharging of the capacitor by using a voltage measured by the voltage measurement part of the determination part 20.

In the measuring of the charging or discharging of the capacitor at S20, the first voltage measurement part 24 may measure the first voltage at the connection point between the first resistor R1 and the first capacitor C1 and provide the first voltage to the controller 30, and the second voltage measurement part 25 may measure the second voltage at the connection point between the second capacitor C2 and the second resistor R2 and provide the second voltage to the controller 30. Changes in the first voltage and the second voltage may indicate charging and discharging of the equivalent capacitor of the first capacitor C1 and the second capacitor C2.

The determining at S30 may be a step in which the controller 30 calculates a voltage of the equivalent capacitor of the first capacitor C1 and the second capacitor C2 by using the first voltage and the second voltage, calculates the loop resistance Rloop by using the first resistor R1 and the second resistor R2, and compares the calculated loop resistance Rloop with a predetermined value.

The determining at S30 may be a step in which the controller 30 measures a time required for the voltage of the capacitor to reach the reference voltage from a point at which the switch 23 configured to generate the pulse voltage is turned on or off, calculates the loop resistance Rloop by dividing the time required for the voltage of the capacitor to reach the reference voltage by the capacitance value of the capacitor connected in series to the high-voltage interlock loop, and determines that the connection state of the connector is abnormal when the loop resistance Rloop exceeds a predetermined value.

In the determining at S30, the controller 30 may calculate the voltage of the equivalent capacitor and may calculate a time required for the voltage of the equivalent capacitor to reach the reference voltage. The time required for the voltage of the equivalent capacitor to reach the reference voltage may start from a point at which the switch 23 is turned on or off. The controller 30 may input the time at which the reference voltage is reached, values of the first resistor R1, the second resistor R2, the third resistor R3, the first capacitor C1, and the second capacitor C2 into Equation 1 to calculate the loop resistance Rloop. The controller 30 may determine that the connection state of the connector 7 is abnormal when the loop resistance Rloop is equal to or greater than a predetermined value. The controller 30 may determine that the connection state of the connector 7 is normal when the loop resistance Rloop is less than the predetermined value.

The connection state determination method may further comprise blocking, by the first capacitor C1 and the second capacitor C2, a high-voltage direct current input from a high-voltage line to the high-voltage interlock loop 6 from flowing into the voltage measurement part, when the high-voltage line is short-circuited to the high-voltage interlock loop 6 at S40.

The determination part 20 may comprise the first capacitor C1 connected in series to the first end of the high-voltage interlock loop 6, the second capacitor C2 connected in series to the second end of the high-voltage interlock loop 6, and the voltage measurement part configured to measure a voltage charged to or discharged from the equivalent capacitor of the first capacitor C1 and the second capacitor C2. When the high-voltage line is short-circuited to the high-voltage interlock loop 6, high-voltage direct current may flow from the high-voltage line to the high-voltage interlock loop 6. Since the first capacitor C1 and the second capacitor C2 are respectively connected to the opposite ends of the high-voltage interlock loop 6, the high-voltage direct current may be prevented from passing through the first capacitor C1 and the second capacitor C2. Accordingly, the first capacitor C1 and the second capacitor C2 may protect electronic components of the determination part 20 from the high-voltage direct current.

The connection state determination apparatus 10 described above may omit a current source installed to supply a constant current to the high-voltage interlock loop 6, may have a simplified structure of a determination circuit for monitoring the high-voltage interlock loop 6, and may allow a capacitor to protect the determination circuit in a high-voltage short-circuit situation.

The present disclosure has been described in detail above through specific embodiments. The foregoing description is merely illustrative of examples in which the principles of the present disclosure are applied, and other configurations may be further comprised without departing from the scope of the present disclosure.

What is claimed is:

1. A connection state determination apparatus comprising:
a determination part comprising a capacitor connected in series to a high-voltage interlock loop comprised in a connector, the determination part being configured to apply a pulse voltage to the high-voltage interlock loop and the capacitor and to measure a voltage charged to or discharged from the capacitor, and
a controller configured to determine a connection state of the connector on the basis of the voltage measured by the determination part,
wherein the controller calculates a loop resistance of the high-voltage interlock loop by using a time required for the voltage of the capacitor to reach a reference voltage and determines the connection state of the connector as abnormal when the loop resistance exceeds a predetermined value.

2. The connection state determination apparatus of claim 1, wherein the determination part further comprises a pulse voltage source configured to supply the pulse voltage,
wherein the pulse voltage source comprises:
a voltage source provided inside a battery management system; and
a switch connected between an output terminal of the voltage source and ground and configured to be repeatedly turned on and off to generate the pulse voltage.

3. The connection state determination apparatus of claim 1, wherein the determination part comprises:
a first capacitor connected in series to a first end of the high-voltage interlock loop;
a second capacitor connected in series to a second end of the high-voltage interlock loop; and
a voltage measurement part configured to measure a voltage across an equivalent capacitance of the first capacitor and the second capacitor,
wherein the first capacitor and the second capacitor protect the voltage measurement part from a high current generated when a high-voltage line is short-circuited to the high-voltage interlock loop.

4. The connection state determination apparatus of claim 1, wherein the determination part comprises:
a first determination part connected to a first end of the high-voltage interlock loop; and
a second determination part connected to a second end of the high-voltage interlock loop,
wherein the first determination part comprises:
a pulse voltage source configured to output the pulse voltage;
a first resistor having a first end connected to the pulse voltage source;
a first capacitor connected in series between a second end of the first resistor and the first end of the high-voltage interlock loop; and
a first voltage measurement part configured to measure a first voltage at a connection point between the first resistor and the first capacitor,
wherein the second determination part comprises:
a second capacitor having a first end connected in series to the second end of the high-voltage interlock loop;
a second resistor connected between a second end of the second capacitor and ground; and
a second voltage measurement part configured to measure a second voltage at a connection point between the second capacitor and the second resistor.

5. The connection state determination apparatus of claim 4, wherein the second determination part comprises:
a third resistor connected between the second resistor and the ground; and
a diode connected in parallel with the third resistor, with an anode of the diode connected to the ground and a cathode of the diode connected to the second resistor.

6. The connection state determination apparatus of claim 1, wherein the determination part and the controller are provided in a battery management system of a battery pack of an electric vehicle.

7. The connection state determination apparatus of claim 2, wherein the time required for the voltage of the capacitor to reach the reference voltage is a time required for the voltage of the capacitor to reach the reference voltage from a point at which the switch configured to generate the pulse voltage is turned on or off.

8. The connection state determination apparatus of claim 1, wherein the controller calculates the loop resistance by dividing the time required for the voltage of the capacitor to reach the reference voltage by a capacitance value of the capacitor connected in series to the high-voltage interlock loop.

9. A connection state determination method comprising:
supplying, by a pulse voltage source of a determination part, a pulse voltage to a high-voltage interlock loop comprised in a connector, the high-voltage interlock loop being connected in series with a capacitor of the determination part;
measuring, by the determination part, charging or discharging of the capacitor; and
determining, by a controller, the connection state of the connector as abnormal when a loop resistance exceeds a predetermined value after calculating the loop resistance of the high-voltage interlock loop by using a time required for a voltage of the capacitor to reach a reference voltage.

10. The connection state determination method of claim 9, wherein the pulse voltage source comprises:
a voltage source provided inside a battery management system; and
a switch connected between an output terminal of the voltage source and ground and configured to be repeatedly turned on and off to generate the pulse voltage,
wherein in the supplying of the pulse voltage, the controller controls the switch to be repeatedly turned on and off.

11. The connection state determination method of claim 9, wherein the determination part comprises:
a first capacitor connected in series to a first end of the high-voltage interlock loop;
a second capacitor connected in series to a second end of the high-voltage interlock loop; and
a voltage measurement part configured to measure a voltage charged to or discharged from an equivalent capacitance of the first capacitor and the second capacitor,
wherein the method further comprises blocking, by the first capacitor and the second capacitor, a high-voltage direct current input from a high-voltage line to the high-voltage interlock loop from flowing into the voltage measurement part, when the high-voltage line is short-circuited to the high-voltage interlock loop.

12. The connection state determination method of claim 9, wherein the determination part comprises:
a first determination part connected to a first end of the high-voltage interlock loop; and
a second determination part connected to a second end of the high-voltage interlock loop,
wherein the first determination part comprises:
the pulse voltage source configured to output the pulse voltage;
a first resistor having a first end connected to the pulse voltage source;
a first capacitor connected in series between a second end of the first resistor and the first end of the high-voltage interlock loop; and
a first voltage measurement part configured to measure a first voltage at a connection point between the first resistor and the first capacitor,
wherein the second determination part comprises:
a second capacitor having a first end connected in series to the second end of the high-voltage interlock loop;
a second resistor connected between a second end of the second capacitor and ground; and
a second voltage measurement part configured to measure a second voltage at a connection point between the second capacitor and the second resistor,
wherein in the measuring of the charging or discharging of the capacitor, the first voltage measurement part measures the first voltage at the connection point between the first resistor and the first capacitor and provides the first voltage to the controller, and the second voltage measurement part measures the second voltage at the connection point between the second capacitor and the second resistor and provides the second voltage to the controller.

13. The connection state determination method of claim 9, wherein in the determining,
the controller measures a time required for the voltage of the capacitor to reach the reference voltage from a point at which a switch configured to generate the pulse voltage is turned on or off, calculates the loop resistance by dividing the time required for the voltage of the capacitor to reach the reference voltage by a capacitance value of the capacitor connected in series to the high-voltage interlock, and determines the connection state of the connector as abnormal when the loop resistance exceeds a predetermined value.
